(19) United States
(12) Patent Application Publication
(10) Pub. No.: US 2025/0126978 A1
(43) Pub. Date: Apr. 17, 2025

(54) DISPLAY BASEPLATE AND DISPLAY PANEL

(71) Applicants: Chengdu BOE Optoelectronics Technology Co., Ltd., Chengdu Sichuan (CN); BOE Technology Group Co., Ltd., Beijing (CN)

(72) Inventors: Bingwei Yang, Beijing (CN); Shun Wang, Beijing (CN); Yingqi Yuan, Beijing (CN)

(73) Assignees: Chengdu BOE Optoelectronics Technology Co., Ltd., Chengdu Sichuan (CN); BOE Technology Group Co., Ltd., Beijing (CN)

(21) Appl. No.: 18/694,530

(22) PCT Filed: Jul. 28, 2023
(86) PCT No.: PCT/CN2023/110002

§ 371 Date: Mar. 22, 2024

(30) Foreign Application Priority Data
Aug. 18, 2022 (CN) 202210996210.5

(51) Int. Cl. H10K 59/122; H10K 59/80

(52) U.S. Cl. CPC H10K 59/122; H10K 59/879; H10K 59/8792

(57) ABSTRACT

A display baseplate and a display panel related to the technical field of display. The display baseplate includes a substrate; a pixel definition layer located on the substrate, wherein the pixel definition layer includes a partition part portion and a plurality of first openings, the partition part comprises a plurality of second openings, and depths of the plurality of first openings along a direction perpendicular to a plane where the substrate is located are greater than depths of the plurality of second openings along the direction perpendicular to the plane where the substrate is located; a plurality of light-emitting units each including a light-emitting functional layer, each first opening is provided with one of the light-emitting functional layers, and at least part of the second openings are provided with the light-emitting functional layers.

### CROSS REFERENCE OF RELATED APPLICATIONS

The present application claims the priority of Chinese patent application filed on Aug. 18, 2022 before the CNIPA, China National Intellectual Property Administration with the application number of 202210996210.5, and the title of “DISPLAY SUBSTRATE AND DISPLAY PANEL”, which is incorporated herein in its entirety by reference.

### TECHNICAL FIELD

The present application relates to the technical field of display and more particularly, to a display baseplate and a display panel.

### BACKGROUND

OLED (Organic Light Emitting Diode) as a new generation display device has advantages such as wide color gamut, flexibility, and foldability. Its benefits are increasingly prominent in fields such as transparent displays, smart wearables, and high-precision displays. However, the scenarios in which OLED devices can be applied are limited due to the existing pixel structure and resolution limitations.

### SUMMARY

The embodiments of the present application disclose the following technical solutions:

In a first aspect, the embodiments of the present application provides a display baseplate, including:
a substrate;
a pixel definition layer located on the substrate, wherein the pixel definition layer includes a partition part and a plurality of first openings, the partition part includes a plurality of second openings, and depths of the plurality of first openings along a direction perpendicular to a plane where the substrate is located are greater than depths of the plurality of second openings along the direction perpendicular to the plane where the substrate is located; and
a plurality of light-emitting units, wherein each of the plurality of light-emitting units including a light-emitting functional layer, each of the plurality of first openings is provided with the light-emitting functional layer, and at least part of the plurality of second openings are provided with the light-emitting functional layers.

In some embodiments of the present application, the depths of the plurality of first openings along the direction perpendicular to the plane where the substrate is located are equal to a thickness of the partition part along the direction perpendicular to the plane where the substrate is located.

In some embodiments of the present application, the display baseplate further includes a plurality of refractive structures located between the substrate and the partition part, orthographic projections of the plurality of refractive structures on the substrate are located within an orthographic projection of the partition part on the substrate, and the orthographic projections of the plurality of refractive structures on the substrate overlap with an area delineated by an orthographic projection of an outer contour of the plurality of second openings on the substrate.

In some embodiments of the present application, each of the plurality of refractive structures includes at least one refractive part, and a refractive index of a material of the at least one refractive part is less than a refractive index of a material of the partition part.

In some embodiments of the present application, each of the plurality of light-emitting units further includes an anode located between the at least one refractive part and the light-emitting functional layer;
wherein, along the direction perpendicular to the plane where the substrate is located, a distance between a surface of a side, close to the substrate, of the anode electrically connected to the light-emitting functional layers in the second openings and a surface of a side of the partition part away from the substrate is less than a distance between a surface of a side of the at least one refractive part away from the substrate and a surface of a side of the partition part away from the substrate.

In some embodiments of the present application, each of the plurality of refractive structures includes a plurality of refractive parts, and the partition part covers the plurality of refractive parts and extends to a region between two adjacent refractive parts; and the anode electrically connected to the light-emitting functional layers in the second openings directly contacts a portion of the partition part located on the sides of the plurality of refractive parts away from the substrate.

In some embodiments of the present application, in a first direction, heights of the plurality of refractive parts gradually decrease along the direction perpendicular to the plane where the substrate is located; wherein, the first direction is a direction pointing from a center of a region where each of the plurality of refractive structures is located to an edge of the region where each of the plurality of refractive structures is located.

In some embodiments of the present application, each of the plurality of refractive structures includes one refractive part, and the display baseplate further includes a plurality of light-absorbing parts located between the refractive part and the anode;
wherein, along the direction perpendicular to the plane where the substrate is located, a distance between surfaces of sides of the plurality of light-absorbing parts close to the substrate and the surface of the side of the partition part away from the substrate is equal to a distance between the surface of the side of the refractive part away from the substrate and the surface of the partition part away from the substrate.

In some embodiments of the present application, each of the plurality of light-emitting units further includes an anode located between the at least one refractive part and the light-emitting functional layer, the light-emitting functional layer is electrically connected to the anode; each of the plurality of refractive structures includes one refractive part;
wherein, along the direction perpendicular to the plane where the substrate is located, a distance between a surface of a side, close to the substrate, of the anode electrically connected to the light-emitting functional layers in the second openings and a surface of a side of the partition part away from the substrate is equal to a distance between a surface of a side of the refractive part away from the substrate and a surface of a side of the partition part away from the substrate.

In some embodiments of the present application, the anode electrically connected to the light-emitting functional layers in the second openings directly contacts the surface of the side of the refractive part away from the substrate.

In some embodiments of the present application, the display baseplate further includes a plurality of light-absorbing parts located between the substrate and the refractive part, and orthographic projections of the plurality of light-absorbing parts on the substrate are located within an orthographic projection of the refractive part on the substrate.

In some embodiments of the present application, the orthographic projections of the plurality of light-absorbing parts on the substrate are located within an orthographic projection of the anode on the substrate, and a distance between an outer contour of the orthographic projections of the plurality of light-absorbing parts on the substrate and an outer contour of the orthographic projection of the anode on the substrate is greater than or equal to 1 μm.

In some embodiments of the present application, the plurality of light-emitting units includes a first light-emitting unit, second light-emitting units, and a third light-emitting unit; and each of the second light-emitting units includes two parts disconnected, and the light-emitting functional layers of the second light-emitting units are located within the second openings.

In some embodiments of the present application, an outer contour of the light-emitting functional layers on the substrate is located within an outer contour of the anode on the substrate, the anode includes a reflective conductive material, and the partition part includes a transparent material.

In some embodiments of the present application, along the direction perpendicular to the plane where the substrate is located, a distance between the light-emitting functional layers in the second openings and a surface of a side of the partition part away from the substrate is greater than zero.

In some embodiments of the present application, a range of refractive indexes of materials of the plurality of refractive structures is 1.4 to 1.7.

In some embodiments of the present application, a pattern of a cross-section of the at least one refractive part along the direction perpendicular to the plane where the substrate is located includes a polygon, an arc, or a combination of the polygon and the arc.

In some embodiments of the present application, the pattern of the cross-section of the at least one refractive part along the direction perpendicular to the plane where the substrate is located includes a trapezoid, and an angle range of a base angle of the trapezoid is 30° to 60°.

In a second aspect, the embodiment of the present application provides a display panel, including the display baseplate described as the first aspect.

The above description is only an overview of the technical solution of the present application. In order to have a clearer understanding of the technical means of the present application, it can be implemented according to the content of the specification. In order to make the above and other purposes, features, and advantages of the present application more obvious and easier to understand, the specific implementation methods of the present application are listed below.

### BRIEF DESCRIPTION OF THE DRAWINGS

In order to more clearly illustrate the technical solutions in the embodiments of the present application or prior art, the drawings needed to be used in the description of the embodiments or prior art will be briefly introduced below. It is evident that the drawings described below are only some embodiments of the present application, and for those skilled in the art, other drawings can be obtained based on these drawings without creative efforts.

FIG. 1 to FIG. 6B are schematic structural diagrams of eight types of display baseplates according to embodiments of the present application, respectively;

FIG. 7 is a top view of a refractive structure according to an embodiment of the present application;

FIG. 8 is a top view of a display baseplate in related art; and

FIG. 9 is a top view of a display baseplate according to an embodiment of the present application.

### DETAILED DESCRIPTION

Below, with reference to the accompanying drawings in the embodiments of the present application, the technical solutions in the embodiments of the present application are clearly and completely described. Apparently, the described embodiments are only part of the embodiments of the present application, not all of them. Based on the embodiments in the present application, all other embodiments obtained by those skilled in the art in the field without creative labor are within the scope protected by the present application.

In the drawings, the thickness of regions and layers may be exaggerated for clarity. Identical or similar structures are denoted by the same reference numerals in the drawings, and therefore, detailed descriptions thereof are omitted. In addition, the drawings are illustrative and not necessarily drawn to scale.

Unless otherwise required by the context, in the entire specification and claims, the term “comprising” is interpreted as open and inclusive, meaning “including, but not limited to”. Terms such as “an embodiment,” “some embodiments,” “exemplary embodiments,” “examples,” “specific examples,” or “some examples” in the description of the specification are intended to indicate that specific features, structures, materials, or characteristics associated with the embodiment or example are included in at least one embodiment or example of the present application. The indicative representations of the above terms do not necessarily refer to the same embodiment or example. Furthermore, the specific features, structures, materials, or characteristics described can be included in any appropriate manner in any one or more embodiments or examples.

In the embodiments of the present application, the use of terms such as “first,” “second,” etc., to distinguish between identical or similar items with substantially the same function and effect is solely for the purpose of describing the technical solutions of the embodiments of the present application clearly, and should not be understood as indicating or implying the relative importance of the indicated technical features or implicitly indicating the quantity of the indicated technical features.

The polygons in this specification are not strictly defined and can be approximately triangular, rectangular, trapezoidal, pentagonal, or hexagonal, etc., and may exhibit some slight deformations due to tolerances, such as fillets, rounded corners, arcs, and deformations, etc.

In this specification, “parallel” and “perpendicular” refer to “approximately parallel” and “approximately perpendicular.” “Parallel” refers to a state where the angle formed by two lines is above −10° and below 10°, and therefore, also includes a state where the angle is above −5° and below 5°. Furthermore, “perpendicular” refers to a state where the angle formed by two lines is above 80° and below 100°, and therefore, also includes a state where the angle is above 85° and below 95°.

Below, a more comprehensive description of exemplary embodiments is provided with reference to the accompanying drawings.

OLED (Organic Light Emitting Diode) as the next-generation display device has advantages such as wide color gamut, flexibility, and foldability. Its advantages are increasingly prominent in fields such as transparent displays, smart wearables, and high-precision display. However, constrained by existing pixel structures, OLED devices face challenges such as difficulty in increasing resolution, light crosstalk, and low luminous efficiency, thereby limiting the application scenarios of OLED devices. The present application provides a new display baseplate aimed at improving the overall performance of OLED devices.

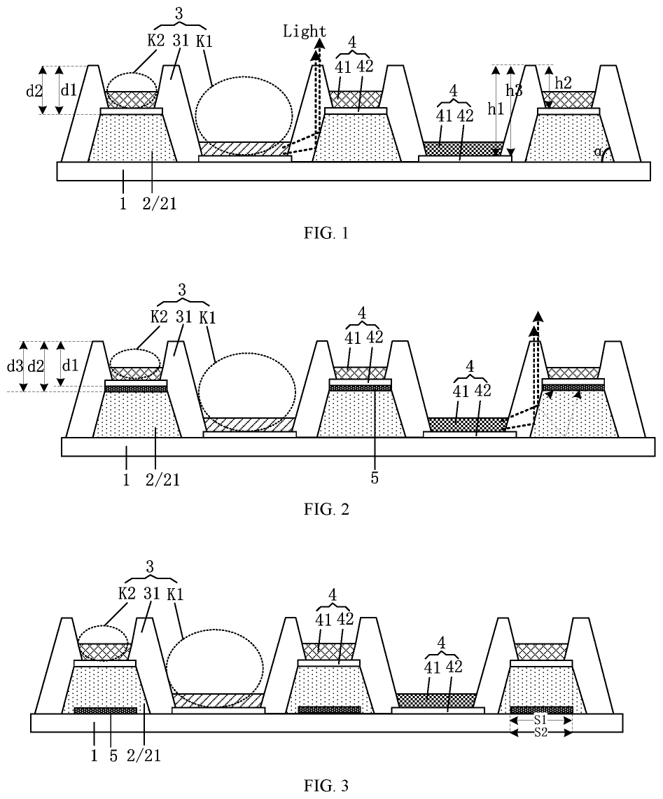

To this end, exemplary embodiments of the present application provide a display baseplate, as shown in FIG. 1, including:
a substrate 1;
a pixel definition layer 3 located on the substrate, wherein the pixel definition layer 3 includes a partition part 31 and a plurality of first openings K1; the partition part 31 includes a plurality of second openings K2, and depths h1 of the first openings K1 along a direction perpendicular to the plane where the substrate 1 is located are greater than depths h2 of the second openings K2 along the direction perpendicular to the plane where the substrate 1 is located; and
a plurality of light-emitting units 4, wherein each light-emitting unit 4 includes a light-emitting functional layer 41, and each first opening K1 is provided with the light-emitting functional layer 41, and at least part of the second openings K2 are provided with the light-emitting functional layers 41.

The type of the substrate 1 is not limited herein. For example, the substrate 1 can be a rigid substrate, such as glass or silicon; alternatively, the substrate 1 can be a flexible substrate, such as flexible polyimide (PI).

When the substrate 1 is the rigid substrate, the above display baseplate can be used to prepare rigid display products; when the substrate is the flexible substrate, the above display baseplate can be used to prepare flexible display products. The Specific can be determined according to the requirements of the products.

The above pixel definition layer (PDL layer) 3 is located in an area (non-light-emitting area) of the display area of the display baseplate except for the light-emitting area (the area provided with OLED light-emitting units). In related art, the pixel definition layer 3 is provided with openings (e.g., first openings K1) at a position corresponding to the light-emitting area, to facilitate the setting of the light-emitting functional layer.

The display area (Active Area, AA) of the above display baseplate refers to an area used for displaying; the light-emitting area (also called the pixel opening area) refers to an area in the display area provided with OLED light-emitting units, and the OLED light-emitting units include an anode, a light-emitting functional layer, and a cathode. In related art, the non-light-emitting area refers to the area in the display area AA except for the light-emitting area, where the pixel definition layer PDL, a pixel circuit unit can be disposed, and the pixel circuit unit may include TFT (Thin Film Transistor), gate lines, data lines, etc.

Among them, the material of the pixel definition layer 3 includes an organic material. The specific type of the organic material included in the pixel definition layer 3 is not limited and can be determined according to actual conditions.

For example, the material of the pixel definition layer 3 may include organic transparent materials, alternatively, the material of the pixel definition layer 3 may include organic opaque (light-absorbing) materials. It should be noted that, due to the pixel definition layer 3 in the related art includes an opaque (light-absorbing) material, according to the definition in the related art, the above-mentioned light-emitting area refers to the area where the OLED light-emitting units are disposed. In the present application, the light-emitting area still refers to the area where the OLED light-emitting units are disposed, without considering the situation where the material of the pixel definition layer 3 is transparent and light may emit.

The pattern of the cross-section of the partition part 31 along the direction perpendicular to the plane where the substrate 1 is located is not limited. For example, pattern of the cross-section of the partition part 31 along the direction perpendicular to the plane where the substrate 1 is located can be a polygonal, such as a quadrilateral, and the quadrilateral may include a trapezoid as shown in FIG. 1.

The shape and size of the pattern of the outer contour of the first opening K1 on the substrate 1 are not limited. Among them, the shape and size of the pattern of the outer contour of the first opening K1 on the substrate 1 can be determined based on the shape and size of the light-emitting unit located in the first opening K1.

The number of second openings K2 disposed on the partition part 31 is not limited and can be determined according to product design. For example, the number of second openings K2 may be less than or equal to the number of first openings K1.

The depths h1 of the first openings K1 along the direction perpendicular to the plane where the substrate 1 is located is greater than the depths h2 of the second openings K2 along the direction perpendicular to the plane where the substrate 1 is located. For example, the depths h1 of the first openings K1 along the direction perpendicular to the plane where the substrate 1 is located can be equal to the thickness of the pixel definition layer 3 along the direction perpendicular to the plane where the substrate 1 is located, and the depths h2 of the second openings K2 along the direction perpendicular to the plane where the substrate 1 is located can be less than the thickness of the pixel definition layer 3 along the direction perpendicular to the plane where the substrate 1 is located.

It should be noted that in the present application, the substrate 1 is a three-dimensional structure, but due to its small size in the thickness direction, it can be approximately regarded as a plane. Therefore, the term “plane where the substrate is located” is used to assist in describing the characteristics of other related structures.

The aforementioned light-emitting units 4 include OLED light-emitting units, which can include an anode, a light-emitting functional layer, and a cathode. The light-emitting functional layer may include a plurality of layers, such as: a hole injection layer (HIL layer), a hole transport layer (HTL layer), an organic transition buffer layer (Prime layer), a luminescent layer (EML layer), a hole blocking layer (HBL layer), and an electron injection layer. The luminous color of the OLED light-emitting units can be determined based on the luminous color of the luminescent layer (EML layer).

The luminous color of the aforementioned light-emitting units is not limited. For example, the aforementioned light-emitting units can be any one of red light-emitting units, green light-emitting units, or blue light-emitting units.

Furthermore, since the display baseplate simultaneously includes the plurality of light-emitting units, the display baseplate can also simultaneously include light-emitting units of three luminous colors: red, green, or blue. Certainly, it can also only include light-emitting units of one luminous color, such as a plurality of red light-emitting units, or a plurality of green light-emitting units, or a plurality of blue light-emitting units. The specific can be determined according to actual requirements.

Among them, at least a part of the second openings K2 is provided with the light-emitting functional layers 41 including the following situations:
1. the light-emitting functional layers 41 are provided in a part of the second openings K2;
2. the light-emitting functional layers 41 are provided in all of the second openings K2.

For example, the aforementioned display baseplate can be applied in the OLED display products. For example, the display baseplate can be applied in silicon-based OLED display products; or the display baseplate can be applied in glass-based OLED display products.

In the display baseplate provided in the embodiment of the present application, the display baseplate includes the substrate 1; the pixel definition layer 3 located on the substrate; the pixel definition layer 3 includes partition part 31 and the plurality of first openings K1; the partition part 31 includes the plurality of second openings K2, where the depths h1 of the first openings K1 along the direction perpendicular to the plane where the substrate 1 is located are greater than the depths h2 of the second openings K2 along the direction perpendicular to the plane where the substrate 1 is located; and the plurality of light-emitting units 4, where each first opening K1 is provided with the light-emitting functional layer 41, and at least a part of the second openings K2 are provided with the light-emitting functional layers 41.

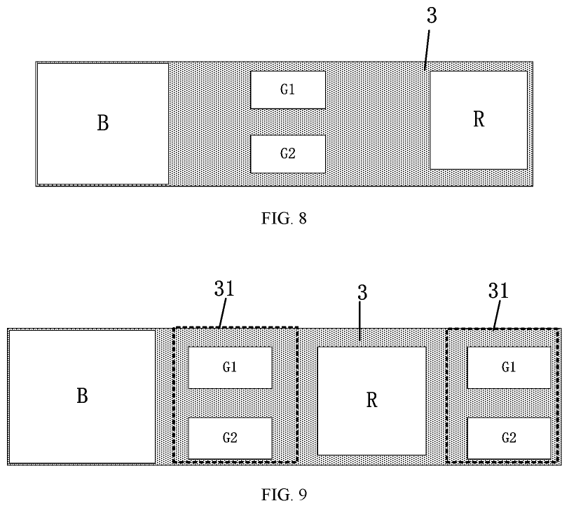

Thus, as shown in FIG. 9, in the embodiment of the present application, the plurality of second openings K2 are provided on the partition part 31 of the pixel definition layer 3. In addition to setting the light-emitting functional layers 41 in the first openings K1, the light-emitting functional layers 41 of the light-emitting units 4 are also provided in at least a part of the second openings K2, significantly reducing the spacing between two adjacent light-emitting units 4 and increasing the design density of the light-emitting units 4 in the display baseplate, thereby improving the resolution of the display baseplate.

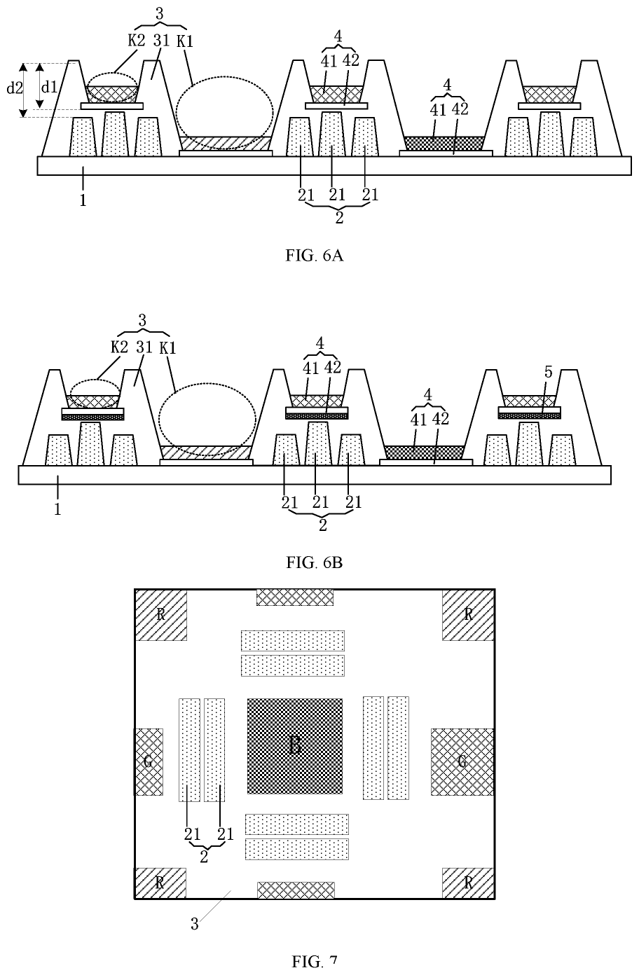

In the related art, as shown in FIG. 8, the pixel definition layer plays a role in defining the pixel light-emitting areas. However, due to process limitations of the material of the pixel definition layer during an evaporation process, the spacing (PDL Gap) of the pixel definition layer between two adjacent sub-pixels cannot be further reduced. Which makes a lower aperture ratio of the OLED display products, for example, the aperture ratio is 20% to 30%. With the difficulty in increasing the aperture ratio, the resolution of the pixels also cannot be further improved.

Compared to the design of light-emitting units in OLED products in the related art shown in FIG. 8, the display baseplate provided in the embodiment of the present application breaks through the limitations on resolution imposed by the pixel (light-emitting unit) design solutions in the related art. It proposes a new design and layout solution for light-emitting units, which can simultaneously increase the aperture ratio and resolution of the display baseplate.

In addition, because the light-emitting functional layers 41 of a part of the light-emitting units are located within the second openings K2, which makes the part of the light-emitting units closer to the light-emitting side of the display baseplate, reducing the propagation path of light and thereby improving the utilization of light.

In practical applications, for all partition parts 31 arranged in an array, in some embodiments, the partition parts 31 provided with the second openings K2 can be arranged at an interval. For example, in the same row of partition parts 31, a first partition part 31 is provided with the second opening K2, the second partition part 31 is not provided with the second opening K2, the third partition part 31 is provided with the second opening K2, and the fourth partition part 31 is not provided with the second opening K2.

In other embodiments, the second openings K2 can be provided on the partition parts 31 in a local area of the display area AA of the display baseplate. For example, in the same row of partition parts 31, the second openings K2 are provided on the first partition part 31 to the tenth partition part 31, and there is no second opening K2 provided on the eleventh partition part 31 to the twentieth partition part 31.

When the second openings K2 are provided on all partition parts 31, for all the second openings K2 arranged in an array, in some embodiments, the second openings K2 provided with the light-emitting functional layers 41 can be arranged at an interval. For instance, in the same row of second openings K2, the first second opening K2 is provided with the light-emitting functional layer 41, the second second opening K2 is not provided with the light-emitting functional layer 41, the third second opening K2 is provided with the light-emitting functional layer 41, and the fourth second opening K2 is not provided with the light-emitting functional layer 41.

In some other embodiments, the light-emitting functional layers 41 can be provided in the second openings K2 of a localized area in the display area (AA) of the display baseplate. For example, for the second openings K2 located in the same row, the first second opening K2 to the tenth second opening K2 are provided with the light-emitting functional layers 41, while the eleventh second opening K2 to the twentieth second opening K2 are not provided with the light-emitting functional layer 41.

Certainly, other scenarios may exist, and the above examples are not meant to limit the position of partition parts 31 with the second openings K2, nor do they restrict the position of the second openings K2 with the light-emitting functional layers 41.

In some embodiments of the present application, the second openings K2 are provided on all partition parts 31, and the light-emitting functional layer 41 is provided in each second opening K2.

In the embodiment of the present application, the second openings K2 are provided on all partition parts 31 of the pixel defining layer 3, and the light-emitting functional layer 41 is provided in each second opening K2, the design density of the light-emitting units of the display baseplate can be greatly increased, thereby more efficiently utilizing the design space on the display baseplate. While ensuring the reasonable layout of each structural design, the aperture rate and resolution of the display substrate can be improved, which is conducive to the preparation of high-performance display products.

In the embodiments of the present application, as shown in FIG. 1, the depths h1 of the first openings K1 along the direction perpendicular to the plane where the substrate 1 is located are equal to the thickness h3 of the partition part 31 along the direction perpendicular to the plane where the substrate 1 is located.

In the embodiments of the present application, each light-emitting unit 4 includes an anode 42 and a light-emitting functional layer 41. In the actual manufacturing process, the anode 42 of the light-emitting unit 4 is formed first, then the pixel definition layer 3 is formed. The light-emitting functional layers 41 are then formed in the first openings K1 of the pixel definition layer 3. Therefore, when the first openings K1 penetrate through the pixel definition layer 3, the depths h1 of the first openings K1 along the direction perpendicular to the plane where the substrate 1 is provided is set to be equal to the thickness h3 of the partition part 31 along the same direction. It should be noted that, the formation of the pixel definition layer 3 includes forming a pixel definition film first, then patterning to form the partition part 31 and the penetrating second openings K2. At this point, the second openings K2 can be understood as large-sized through-holes, which can expose a part region of the anode 42 located between the pixel definition layer 3 and the substrate 1, thus enabling direct contact and electrical connection between the anode 42 and the light-emitting functional layer 41.

In some embodiments of the present application, as shown in FIG. 1, the display baseplate further includes a plurality of refractive structures 2. The refractive structures 2 are located between the substrate 1 and the partition part 31, the orthographic projections of the refractive structures 2 on the substrate 1 are located within the orthographic projection of the partition part 31 on the substrate 1, and the orthographic projections of the refractive structures 2 on the substrate 1 overlap a region delineated by an orthographic projection of the outer contour of the second openings K2 on the substrate 1.

In exemplary embodiments, the orthographic projections of the refractive structures 2 on the substrate 1 is located within the orthographic projection of the partition part 31 on the substrate 1, including the following situations:
firstly, the outer contour of the orthographic projections of the refractive structures 2 on the substrate 1 is located within the outer contour of the orthographic projection of the partition part 31 on the substrate 1; and
Secondly, the outer contour of the orthographic projections of the refractive structures 2 on the substrate 1 overlaps with the outer contour of the orthographic projection of the partition part 31 on the substrate 1.

It is noted that in this specification, “overlap” refers to at least partial overlap.

In some embodiments of the present application, as shown in FIG. 1 and FIG. 5A, the refractive structure 2 includes at least one refractive part 21, and the refractive index of the material of the refractive part 21 is less than the refractive index of the material of the partition part 31.

In some embodiments, as shown in FIG. 1, the refractive structure 2 includes one refractive part 21; in other embodiments, as shown in FIG. 5A, the refractive structure 2 includes three refractive parts 21.

It should be noted that in the case where one refractive structure 2 includes a plurality of refractive parts 21, there is no restriction on whether there is a gap between two adjacent refractive parts 21.

For example, there may be a gap between two adjacent refractive parts 21 in the same refractive structure 2; alternatively, the two adjacent refractive parts 21 in the same refractive structure 2 may directly contact each other. In the drawings provided in the embodiments of the present application, an example is depicted where there is a gap between the two adjacent refractive parts 21 in the same refractive structure 2.

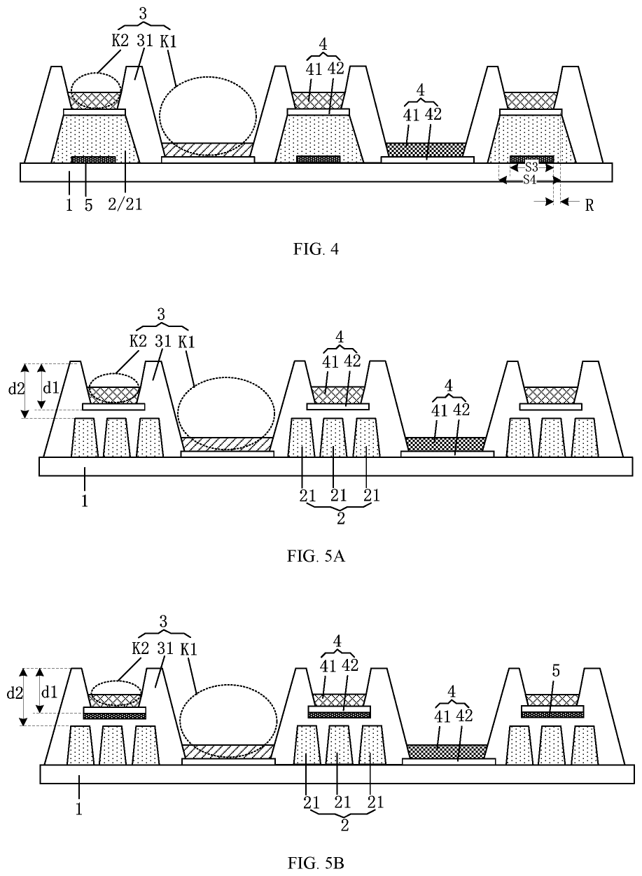

The shape of the orthographic projection of the refractive parts 21 on the substrate 1 is not limited. For example, the shape of the orthographic projection of the refractive parts 21 on the substrate 1 can include polygons, arcs, and combinations of the arcs and the polygons. For example, the polygons may include quadrilaterals as shown in FIG. 7, the arcs may include circles, and the shape formed by the combination of the arcs and the polygons may include rounded quadrilaterals. The specific shape can be determined based on practical considerations.

The shape of the pattern of the cross-section of the refractive part 21 along the direction perpendicular to the plane where the substrate 1 is located is not limited herein. For example, the shape of the pattern of the cross-section of the refractive part 21 along the direction perpendicular to the plane where the substrate 1 is located can include polygons, arcs, and shapes formed by a combination of the arcs and the polygons. In the embodiments provided in the present application, the shape of the pattern of the cross-section of the refractive part 21 along the direction perpendicular to the plane where the substrate 1 is located is illustrated as a trapezoid.

The material of the refractive part 21 is not limited. For example, the material of the refractive part 21 can include inorganic transparent materials, such as, at least one of silicon nitride (SiNx), silicon oxide (SiO₂), or silicon oxynitride (SiNxOy).

The material of the partition part 31 is not limited. For example, the material of the partition part 31 can include organic transparent materials, such as organic resins.

In exemplary embodiments, the range of the refractive index of the material of the partition part 31 can be 1.8 to 2.2.

In the embodiments of the present application, refractive structures 2 are provided between the partition part 31 and the substrate 1, the refractive index of the material of the refractive structures 2 is less than that of the material of the partition part 31, the partition part 31 is an optically denser medium, and the refractive structure 2 is an optically thinner mediums, most of the light undergoes reflection at the interface between the two mediums when light passes from an optically denser medium to the optically thinner medium. Specifically, when light emitted from the side of the light-emitting unit 4 directly contact the partition part 31 enters the partition part 31, as indicated by the position marked “Light” in FIG. 1,. most of the light is reflected out from the partition part 31 due to the reflection effect at the interface. In this way, which significantly improves the luminous efficiency of the positive viewing angle of the display panel, reducing power consumption.

In some embodiments of the present application, as shown in FIG. 2, FIG. 5A, and FIG. 5B, the light-emitting unit 4 also includes an anode 42 located between the refractive part 2 and the light-emitting functional layer 41.

In the direction perpendicular to the plane where the substrate 1 is located, the distance d1 between the surface of the side, close to the substrate 1, of the anode 42 electrically connected to the light-emitting functional layer 41 in the second opening K2 and the surface of the side of the partition part 31 away from the substrate 1 is less than the distance d2 between the surface of the side of the refractive part 21 away from the substrate 1 and the surface of the side of the partition part 31 away from the substrate 1.

The material of the anode 42 is not limited herein. For example, the material of the anode 42 can include transparent conductive materials such as indium tin oxide (ITO) and other semiconductor materials; alternatively, the material of the anode 42 can include opaque conductive materials such as copper (Cu) and other metal materials.

In some embodiments, as shown in FIG. 2, the depth of the second opening K2 is large, so that there is no material of the partition part 31 between the anode 42 and the refractive part 21. In addition, the display baseplate further includes a light-absorbing part 5, which is located between the anode 42 and the refractive part 21, a surface of a side of the light-absorbing part 5 away from the substrate 1 is in contact with the anode 42, and a surface of a side of the light-absorbing part 5 close to the substrate 1 is in contact with the refractive part 21. Thus, the distance d2 between the surface of the side of the refractive part 21 away from the substrate 1 and the surface of the side of the partition part 31 away from the substrate 1 is equal to the sum of the distance d1 and the thickness of the light-absorbing part 5 in the direction perpendicular to the plane where the substrate 1 is located, among them, the distance d1 is a distance between the surface of the side, close to the substrate 1, of the anode 42 electrically connected to the light-emitting functional layer 41 in the second opening K2 and the surface of the side of the partition part 31 away from the substrate 1.

In the embodiments of the present application, as shown in FIG. 2, when light emitted from the light-emitting unit 4 enters the partition part 31 from the side, at the interface between the two mediums, the light mainly undergoes reflection. Additionally, a small part of the light enters the refractive structure 2 from the partition part 31. The light entering the refractive structure 2 can be absorbed by the light-absorbing part 5, thereby greatly improving the problem of light crosstalk between adjacent light-emitting units of different colors and enhancing the display effect.

In some embodiments, as shown in FIG. 5A, the depth of the second opening K2 is small, so that there is still material of the partition part 31 between the anode 42 and the refractive part 21. In this way, the distance d1 between the surface of the side, close to the substrate 1, of the anode 42 electrically connected to the light-emitting functional layer 41 in the second opening K2 and the surface of the side of the partition part 31 away from the substrate 1 is less than the distance d2 between the surface of the side of the refractive part 21 away from the substrate 1 and the surface of the side of the partition part 31 away from the substrate 1, and the difference between d2 and dl is determined based on the thickness of the material of the partition part 31 located between the anode 42 and the refractive part 21.

In another embodiment, as shown in FIG. 5B, the depth of the second opening K2 is small, so that there is still material of the partition part 31 between the anode 42 and the refractive part 21. Additionally, the display baseplate further includes a light-absorbing part 5 located between the anode 42 and the refractive part 21. Thus, the difference between d2 and dl is determined based on the thickness of the material of the partition part 31 located between the anode 42 and the refractive part 21, as well as the thickness of the light-absorbing part 5.

In some embodiments of the present application, as shown in FIG. 5A, the refractive structure 2 includes a plurality of refractive parts 21, and the partition part 31 covers the refractive parts 21 and extends to the area between two adjacent refractive parts 21. The anode 42 electrically connected to the light-emitting functional layer 41 in the second opening K2 is in directly contact with a part of the partition part 31 located on the side of the refractive part 21 away from the substrate 1.

In FIG. 5A, because the refractive structure 2 includes the plurality of refractive parts 21, the surface of the side of the refractive structure 2 away from the substrate 1 is not flat.

Forming the anode 41 on such a surface increases the difficulty of the manufacturing process and significantly increases the possibility of cracks on the surface of the anode 41, leading to the anode 41 fracture. In the embodiments of the present application, a material of the partition part 31 is provided between the anode 41 and the refractive structure 2, when this material flows flat to form a flat surface, and then the anode 41 or other structure is formed, which not only reduces the difficulty of the preparation process, but also improves the yield of the preparation of the display baseplate, and saves costs.

In some other embodiments, as shown in FIG. 5B, the refractive structure 2 includes the plurality of refractive parts 21, and the partition part 31 covers the plurality of refractive parts 21 and extends to the area between the two adjacent refractive parts 21. The light-absorbing part 5 is further provided between the anode 42 electrically connected to the light-emitting functional layer 41 in the second opening K2 and the refractive parts 21. Moreover, the light-absorbing part 5 is in direct contact with a part of the partition part 31 located on the side of the refractive part 21 away from the substrate 1. Which allows the light-absorbing part 5 to absorb light that has not emitted from the partition part 31, thereby avoiding light crosstalk between two adjacent light-emitting units 4 of different colors, thereby enhancing the color purity of the display panel and improving the display performance.

In some embodiments of the present application, as shown in FIG. 6A and FIG. 6B, along a first direction, the heights of the refractive parts 21 gradually decrease along the direction perpendicular to the plane where the substrate 1 is located; the first direction is a direction pointing from the center of the region where the refractive structure 2 is located to the edge of the region where the refractive structure 2 is located.

The center of the region where the refractive structure 2 is located refers to the region located in the center, not a position of the center. Similarly, the above edge refers to the region located at the edge of the central, not the outer contour position of the region where refractive structure 2 is located.

In the embodiment of the present application, when some light rays enters the refractive part 21 from the partition part 31, the height of the refractive part 21 in the central region is set to be greater than that of the refractive part 21 in the edge region, so that as many light rays as possible can undergo refraction of the refractive part 21 in the edge region and the refractive part 21 in the central region sequentially, and then be emitted out from the partition part 31. Thereby further improving the luminous efficiency of the positive viewing angle of the display panel, enhancing the display effect, and reducing power consumption.

In some embodiments of the present application, as shown in FIG. 2, the refractive structure 2 includes one refractive part 21, and the display baseplate further includes a plurality of light-absorbing parts 5 located between the refractive part 21 and the anode 42;
along the direction perpendicular to the plane where the substrate 1 is located, the distance d2 between the surface of the side of the light-absorbing part 5 close to the substrate 1 and the surface of the side of the partition part 31 away from the substrate 1 is equal to the distance d3 between the surface of the side of the refractive part 21 away from the substrate 1 and the surface of the side of the partition part 31 away from the substrate 1.

In the embodiment of the present application, as shown in FIG. 2, when light emitted from the light-emitting unit 4 enters the partition part 31 from the side, at the interface between the two mediums, the light mainly undergoes reflection. Additionally, a small part of the light enters the refractive structure 2 from the partition part 31. The light entering the refractive structure 2 can be absorbed by the light-absorbing part 5, thereby greatly improving the problem of light crosstalk between adjacent light-emitting units of different colors and enhancing the display effect.

In some embodiments of the present application, as shown in FIG. 1, FIG. 3, and FIG. 4, the light-emitting unit 4 further includes an anode 42 located between the refractive part 21 and the light-emitting functional layer 41; the refractive structure 2 includes one refractive part 21. Along the direction perpendicular to the plane where the substrate 1 is located, the distance d1 between the surface of the side, close to the substrate 1, of the anode 42 electrically connected to the light-emitting functional layer 41 in the second opening K2 and the surface of the side of the partition part 31 away from the substrate 1 is equal to the distance d2 between the surface of the side of the refractive part 21 away from the substrate and the surface of the side of the partition part 31 away from the substrate.

In some embodiments of the present application, for both the partition part 31 and the refractive structure 2, the partition part 31 is an optically denser medium, while the refractive structure 2 is an optically thinner medium, when light enters the optically thinner medium from the optically denser medium, at the interface between the two mediums, light primarily undergoes reflection. Due to the direct contact between the side surface of the light-emitting unit 4 and the partition part 31, when light emitted from the light-emitting unit 4 enters the partition part 31 from the side, this reflection causes most of the light to exit the partition part 31. Consequently, this significantly enhances the luminous efficiency of the positive viewing angle of the display panel, reduces power consumption, and lowers costs.

In some embodiments of the present application, as shown in FIG. 1, FIG. 3, and FIG. 4, the anode 42 electrically connected to the light-emitting functional layer 41 in the second opening K2 directly contacts the surface of the side of the refractive part 21 away from the substrate 1.

In practical applications, the anode 42 is designed to directly contact the refractive structure 21, which may simplify the design of the display baseplate, reduces the complexity of manufacturing processes, shortens production cycles, and further reduces costs.

In some embodiments of the present application, as shown in FIG. 3 and FIG. 4, the display baseplate further includes a plurality of light-absorbing parts 5 located between the substrate 1 and the refractive part 21, and the orthographic projection of the light-absorbing part 5 on the substrate 1 is located within the orthographic projection of the refractive part 21 on the substrate 1.

The orthographic projection of the light-absorbing part 5 on the substrate 1 is located within the orthographic projection of the refractive part 21 on the substrate 1, including but not limited to the following situations:
as shown in FIG. 3, the outer contour of the orthographic projection S1 of the light-absorbing part 5 on the substrate 1 overlaps with the outer contour of the orthographic projection S2 of the refractive part 21 on the substrate 1;
alternatively, as shown in FIG. 4, the outer contour of the orthographic projection of the light-absorbing part 5 on the substrate 1 is located within the outer contour of the orthographic projection of the refractive part 21 on the substrate 1.

In exemplary embodiments, the materials of the light-absorbing parts 5 include light-absorbing materials, for example, black resin, for another example, materials same as the black matrix (BM).

Consequently, light that is not reflected by the refractive structure 21 upon entering the refractive part 21 may directly enter the light-absorbing parts 5 and be absorbed, or it may be reflected by the anode 42 and then enter the light-absorbing parts 5 to be absorbed. Which largely avoids the problem of light cross-talk between adjacent light-emitting units 4 of different colors, thereby improving the color purity of the display baseplate and enhancing display performance.

In some embodiments of the present application, as shown in FIG. 4, the orthographic projection S3 of the light-absorbing part 5 on the substrate 1 is located within the orthographic projection S4 of the anode 42 on the substrate 1, and the distance R between the outer contour of the orthographic projection S3 of the light-absorbing part 5 on the substrate 1 and the outer contour of the orthographic projection S4 of the anode 42 on the substrate 1 is greater than or equal to 1 μm.

In some embodiments of the present application, the distance between the outer contour of the orthographic projection S3 of the light-absorbing part 5 on the substrate 1 and the outer contour of the orthographic projection S4 of the anode 42 on the substrate 1 is greater than or equal to 1 μm, the anode 42 is located on the upper surface of the refractive part 21 and the light-absorbing part 5 is close to the lower surface of the refractive part 21, due to the limitations of the material preparation process for the refractive part 21, for the actual product, it ultimately ensures that the distance between the outer contour of the orthographic projection S3 of the light-absorbing part 5 on the substrate 1 and the outer contour of the orthographic projection of the refractive part 21 on the substrate 1 is also greater than or equal to 1 μm, thereby allowing the refractive part 21 to cover the light-absorbing part 5 and extend to the areas at both sides of the light-absorbing part 5. Consequently, there may still be some light rays are not absorbed by the light-absorbing part 5 after entering the refractive part 21, and are emitted from the partition part 31 after being reflected by the substrate 1. While the light-absorbing part 5 improves the problem of light cross-talk, it further enhances the brightness of the positive viewing angle of the display baseplate and improves display performance.

In some embodiments of the present application, as shown in FIG. 1, the plurality of light-emitting units 3 include a first light-emitting unit, a second light-emitting unit, and a third light-emitting unit, wherein the second light-emitting unit includes two parts that are disconnected, and the light-emitting functional layer 41 of each second light-emitting unit is located in the second opening K2.

For example, the first light-emitting unit can be a red light-emitting unit, the third light-emitting unit can be a blue light-emitting unit, and the second light-emitting unit can be a green light-emitting unit. This design can be referred to as GGRB pixel design.

The accompanying drawings provided in embodiments of the present application depict the scenario where the light-emitting functional layer 41 of each second light-emitting unit is located in the second opening K2, while the light-emitting functional layers 41 of each first light-emitting unit and each third light-emitting unit are located in the first openings K1.

In some embodiments of the present application, as shown in FIG. 1, the outer contour of the orthographic projection of the light-emitting functional layer 41 on the substrate 1 is located within the outer contour of the orthographic projection of the anode 42 on the substrate 1. The anode 42 includes a reflective conductive material, and the partition part 31 includes a transparent material.

In the related art, the pixel definition layer includes a light-absorbing coating or a light-blocking coating, therefore, the pixel definition layer has a light-blocking function to avoid light cross-talk, but their utilization efficiency of light is very low. In embodiments of the present application, the partition part 31 is set to include the transparent material, and the refractive part 21 is disposed between the partition part 31 and the substrate 1. Through the reflection and refraction between these two structures, the luminous efficiency in the positive viewing angle is improved, and the light cross-talk is reduced to some extent at the same time. Additionally, the additional provided light-absorbing part 5, as shown in FIG. 2 or FIG. 3, can further reduce light cross-talk while ensuring luminous efficiency in the positive viewing angle, thereby improving display performance.

In some embodiments of the present application, along the direction perpendicular to the plane where the substrate 1 is located, the distance between the light-emitting functional layer 41 in the second opening K2 and the surface of the side of the partition part 31 away from the substrate 1 is greater than zero. In this way, which allows for isolation between the light-emitting functional layers 41 in the first openings K1 and the light-emitting functional layers 41 in the second openings K2. During the preparation of the light-emitting functional layers 41 in the second openings K2, contact with adjacent light-emitting functional layers 41 in the first openings K1 is avoided, thereby preventing the mixing of light-emitting functional materials.

In some embodiments of the present application, the range of the refractive index of the material of the refractive structure is 1.4 to 1.7.

For example, the refractive index of the material of the refractive structure can include 1.4, 1.5, 1.6, or 1.7.

In some embodiments of the present application, the pattern of the cross-section of the refractive part 21 along the direction perpendicular to the plane where the substrate 1 is located includes polygons, arcs, or combinations of the polygons and the arcs.

In some embodiments of the present application, as shown in FIG. 1, the pattern of the cross-section of the refractive part 21 along the direction perpendicular to the plane where the substrate 1 is located includes a trapezoid, where the range of the base angle a of the trapezoid is 30° to 60°.

The trapezoid includes a group of first side edge and second side edge that are parallel to each other, the length of the first side edge is greater than the length of the second side edge. The first side edge is called the bottom base, and the second side edge is called the top base. It also includes a third side edge and a fourth side edge for connecting the first side edge and the second side edge, the angle between the third side edge and the first side edge, as well as the angle between the fourth side edge and the first side edge, are both referred to as the base angle of the trapezoid.

For example, the base angle a of the trapezoid can be 30°, 35°, 40°, 45°, 50°, or 60°.

In exemplary embodiments, the range of the length of the base of the aforementioned trapezoid includes 3 μm to 10 μm, and the height of the trapezoid includes 1 μm to 3 μm.

For example, the length of the base of the trapezoid can include 3 μm, 4 μm, 5 μm, or 6 μm, and the height of the trapezoid can include 1.2 μm, 1.5 μm, 1.8 μm, 2 μm, or 2.5 μm.

In embodiments of the present application, when the pattern of the cross-section of the refractive part 21 along the direction perpendicular to the plane where the substrate 1 is located includes the trapezoid, with the base angle a ranging from 30° to 60°, the brightness of the positive viewing angle of the display baseplate is increased, and the light utilization rate is high, which significantly improves display performance and reduces power consumption.

The embodiments of the present application provide a display panel, including the display baseplate as described above.

The structure of the display baseplate mentioned above can be referred to the description in the previous text, which will not be reiterated here.

In addition, the aforementioned display panel may include OLED (Organic Light Emitting Diode) display panels, such as glass-based OLED display panels, or silicon-based OLED display panels.

The embodiments of the present application provide a display device, including the display panel as described above. The display device can be a display device such as an OLED display, and can be TVs, digital cameras, mobile phones, tablet computers, or any product or component with display functionality including the display device. The display device has high luminous efficiency of the positive viewing angle, high color purity, and good display performance.

The above-described embodiments are only specific embodiments of the present application. However, the scope of protection of the present application is not limited thereto. Any changes or substitutions that can be easily conceived by those skilled in the art within the technical scope disclosed in the present application should be encompassed within the scope of protection of the present application. Therefore, the scope of protection of the present application should be determined by the scope of protection of the claims.

1. A display baseplate, comprising:
a substrate;
a pixel definition layer located on the substrate, wherein the pixel definition layer comprises a partition part and a plurality of first openings, the partition part comprises a plurality of second openings, and depths of the plurality of first openings along a direction perpendicular to a plane where the substrate is located are greater than depths of the plurality of second openings along the direction perpendicular to the plane where the substrate is located; and
a plurality of light-emitting units, wherein each of the plurality of light-emitting units comprising a light-emitting functional layer, each of the plurality of first openings is provided with the light-emitting functional layer, and at least part of the plurality of second openings are provided with the light-emitting functional layers.

2. The display baseplate according to claim 1, wherein the depths of the plurality of first openings along the direction perpendicular to the plane where the substrate is located are equal to a thickness of the partition part along the direction perpendicular to the plane where the substrate is located.

3. The display baseplate according to claim 1, wherein the display baseplate further comprises a plurality of refractive structures located between the substrate and the partition part, orthographic projections of the plurality of refractive structures on the substrate are located within an orthographic projection of the partition part on the substrate, and the orthographic projections of the plurality of refractive structures on the substrate overlap with an area delineated by an orthographic projection of an outer contour of the plurality of second openings on the substrate.

4. The display baseplate according to claim 3, wherein each of the plurality of refractive structures comprises at least one refractive part, and a refractive index of a material of the at least one refractive part is less than a refractive index of a material of the partition part.

5. The display baseplate according to claim 4, wherein each of the plurality of light-emitting units further comprises an anode located between the at least one refractive part and the light-emitting functional layer;
wherein, along the direction perpendicular to the plane where the substrate is located, a distance between a surface of a side, close to the substrate, of the anode electrically connected to the light-emitting functional layers in the second openings and a surface of a side of the partition part away from the substrate is less than a distance between a surface of a side of the at least one refractive part away from the substrate and a surface of a side of the partition part away from the substrate.

6. The display baseplate according to claim 5, wherein each of the plurality of refractive structures comprises a plurality of refractive parts, and the partition part covers the plurality of refractive parts and extends to a region between two adjacent refractive parts; and
the anode electrically connected to the light-emitting functional layers in the second openings directly contacts a portion of the partition part located on the sides of the plurality of refractive parts away from the substrate.

7. The display baseplate according to claim 6, wherein in a first direction, heights of the plurality of refractive parts gradually decrease along the direction perpendicular to the plane where the substrate is located;
wherein, the first direction is a direction pointing from a center of a region where each of the plurality of refractive structures is located to an edge of the region where each of the plurality of refractive structures is located.

8. The display baseplate according to claim 5, wherein each of the plurality of refractive structures comprises one refractive part, and the display baseplate further comprises a plurality of light-absorbing parts located between the refractive part and the anode;
wherein, along the direction perpendicular to the plane where the substrate is located, a distance between surfaces of sides of the plurality of light-absorbing parts close to the substrate and the surface of the side of the partition part away from the substrate is equal to a distance between the surface of the side of the refractive part away from the substrate and the surface of the partition part away from the substrate.

9. The display baseplate according to claim 4, wherein each of the plurality of light-emitting units further comprises an anode located between the at least one refractive part and the light-emitting functional layer, the light-emitting functional layer is electrically connected to the anode;
each of the plurality of refractive structures comprises one refractive part;
wherein, along the direction perpendicular to the plane where the substrate is located, a distance between a surface of a side, close to the substrate, of the anode electrically connected to the light-emitting functional layers in the second openings and a surface of a side of the partition part away from the substrate is equal to a distance between a surface of a side of the refractive part away from the substrate and a surface of a side of the partition part away from the substrate.

10. The display baseplate according to claim 9, wherein the anode electrically connected to the light-emitting functional layers in the second openings directly contacts the surface of the side of the refractive part away from the substrate.

11. The display baseplate according to claim 10, wherein the display baseplate further comprises a plurality of light-absorbing parts located between the substrate and the refractive part, and orthographic projections of the plurality of light-absorbing parts on the substrate are located within an orthographic projection of the refractive part on the substrate.

12. The display baseplate according to claim 11, wherein the orthographic projections of the plurality of light-absorbing parts on the substrate are located within an orthographic projection of the anode on the substrate, and a distance between an outer contour of the orthographic projections of the plurality of light-absorbing parts on the substrate and an outer contour of the orthographic projection of the anode on the substrate is greater than or equal to 1 μm.

13. The display baseplate according to claim 5, wherein the plurality of light-emitting units comprises a first light-emitting unit, second light-emitting units, and a third light-emitting unit; and
each of the second light-emitting units comprises two parts disconnected, and the light-emitting functional layers of the second light-emitting units are located within the second openings.

14. The display baseplate according to claim 3, wherein each of the plurality of light-emitting units further comprises an anode located between the at least one refractive part and the light-emitting functional layer, an outer contour of orthographic projections of the light-emitting functional layers on the substrate is located within an outer contour of an orthographic projection of the anode on the substrate, the anode comprises a reflective conductive material, and the partition part comprises a transparent material.

15. The display baseplate according to claim 14, wherein along the direction perpendicular to the plane where the substrate is located, a distance between the light-emitting functional layers in the second openings and a surface of a side of the partition part away from the substrate is greater than zero.

16. The display baseplate according to claim 15, wherein a range of refractive indexes of materials of the plurality of refractive structures is 1.4 to 1.7.

17. The display baseplate according to claim 4, wherein a pattern of a cross-section of the at least one refractive part along the direction perpendicular to the plane where the substrate is located comprises a polygon, an arc, or a combination of the polygon and the arc.

18. The display baseplate according to claim 17, wherein the pattern of the cross-section of the at least one refractive part along the direction perpendicular to the plane where the substrate is located comprises a trapezoid, and an angle range of a base angle of the trapezoid is 30° to 60°.

19. A display panel, comprising the display baseplate according to claim 1.
